(19) United States
(12) Patent Application Publication
(10) Pub. No.: US 2012/0205615 A1
(43) Pub. Date: Aug. 16, 2012

(54) ORGANIC PHOTOVOLTAIC CELL

(76) Inventors: Takahiro Seike, Ibaraki (JP); Toshihiro Ohnishi, Ibaraki (JP); Yutaka Ito, Ibaraki (JP)

(21) Appl. No.: 13/504,654

(22) PCT Filed: Oct. 22, 2010
(86) PCT No.: PCT/JP2010/068734

§ 371 Date: Apr. 27, 2012

(30) Foreign Application Priority Data
Oct. 29, 2009 (JP) 2009 249517

(51) Int. Cl. H01L 31/0264; B82Y 99/00; B82Y 40/00

(52) U.S. Cl. 257/9; 438/85; 257/E31.004; 977/773

(57) ABSTRACT

An organic photovoltaic cell (10) of the present invention includes an active layer (40) containing an organic compound and being provided between a pair of electrodes of a first electrode (32) and a second electrode (34), and because the active layer contains metallic oxide nano-particles wearing a carbon material on its surface, the organic photovoltaic cell can be manufactured from an inexpensive material.

### TECHNICAL FIELD

The present invention relates to an organic photovoltaic cell and a device provided with the organic photovoltaic cell.

### BACKGROUND ART

A photovoltaic cell, comprised in a solar cell that converts light into electrical power, or in an image sensor that converts an image into an electrical signal and in the like, has been studied and considered for practical use. In a photovoltaic cell of which practical use has been promoted, an inorganic semiconductor material is usually used in an active layer having a light-electricity conversion activity. On the other hand, in view of achieving a thinner and larger cell, a photovoltaic cell in which an organic compound material is used in the active layer having a light electricity conversion activity, has attracted attention. (Hereinafter, such the photovoltaic cell is referred to as an organic photovoltaic cell.)

Conventionally, as an n-type semiconductor material for an organic photovoltaic cell, a fullerene derivative, for example, PCBM([6,6]-Phenyl-C₆₁-Butyric Acid Methyl Ester) is used. However, PCBM is very expensive, and therefore, a less expensive n-type semiconductor material has been required.

Although, as one candidate for an alternative material to PCBM, use of metallic oxide nano-particles capable of serving as an n-type semiconductor material has been studied, metallic oxide nano-particles tend to decrease the light-electricity conversion efficiency as compared with PCBM. For an improvement of a light-electricity conversion property, improvement of n-type metallic oxide nano-particles has been attempted. For example, a test has been carried out using TOPO-capped TiO₂, which is nanocrystal TiO₂(nc-TiO₂) of which surface is capped with trioctyl phosphine oxide (TOPO), and the like (Non Patent Document 1).

### RELATED ART DOCUMENTS

Non Patent Document 1: Johann et al., Advanced Functional Materials, 18(2008)662, Hybrid Solar Cells from a Blend of Poly(3-hexylthiophene) and Lignad-Capped TiO2 Nanorods

### DISCLOSURE OF INVENTION

### Problem to be Solved by the Invention

Usually, the surface of a metallic oxide is easily covered with a hydroxy group. Also, because nano-particles have high surface energy, cohesive force in a solid state is strong. Therefore, metallic oxide nano-particles can easily form gross secondary cohesion having several micrometers. When n-type metallic oxide nano-particles are used, a fine mixed state at nanometric (nm) level, which is called bulk hetero-junction structure, cannot be easily formed with a p-type organic macromolecular, unlike the case of PCBM. The inventors of the present invention have found that a preferable material for a semiconductor material capable of being used for an organic photovoltaic cell can be obtained at low cost by putting a carbon material on metallic oxide, thereby completed the present invention. The present invention provides the following organic photovoltaic cell.

[1] An organic photovoltaic cell comprising:

a pair of electrodes of a first electrode and a second electrode; and

an active layer comprising an organic compound, provided between the pair of electrodes,

wherein the active layer comprises a metallic oxide nano-particle wearing a carbon material on its surface.

[2] The organic photovoltaic cell according to [1], wherein the carbon material is selected from the group consisting of a graphite, a fullerene, a fullerene derivative and a carbon nanotube.

[3] The organic photovoltaic cell according to [1] or [2], wherein the metallic oxide constituting the metallic oxide nano-particle is an n-type semiconductor material.

[4] The organic photovoltaic cell according to any one of [1] to [3], wherein the metallic oxide constituting the metallic oxide nano-particle is a metallic oxide made from a metal selected from the group consisting of Ti, Nb, Zn, and Sn.

[5] A method for manufacturing an organic photovoltaic cell comprising a pair of electrodes of a first electrode and a second electrode, and an active layer comprising an organic compound and being provided between the pair of electrodes, the manufacturing method comprising the step of:

forming the active layer comprising a metallic oxide nano-particle wearing a carbon material on its surface.

[6] The method for manufacturing an organic photovoltaic cell according to [5], wherein the metallic oxide nano-particle wearing a carbon material on its surface is produced by a particle-preparation method including the steps (A) and (B):

(A) preparing a mixed solution of a slurry comprising a raw material of the metallic oxide and a raw material of the carbon material; and

(B) performing a supercritical water heat treatment to the mixed solution.

[7] An organic photovoltaic cell manufactured by the method according to [6], wherein the raw material of the carbon material is a saccharide.

[8] A solar cell module comprising the organic photovoltaic cell according to any one of [1] to [4].

[9] An image sensor device comprising the organic photovoltaic cell according to any one of [1] to [4].

### BRIEF DESCRIPTION OF DRAWINGS

FIG. 1 illustrates a layer structure of an organic photovoltaic cell of a first embodiment of the present invention.

FIG. 2 illustrates a layer structure of an organic photovoltaic cell of a second embodiment of the present invention.

FIG. 3 illustrates a layer structure of an organic photovoltaic cell of a third embodiment of the present invention.

### EXPLANATIONS OF LETTERS OR NUMERALS

10 organic photovoltaic cell
20 substrate
32 first electrode
4 second electrode
40 active layer
42 first active layer
44 second active layer
52 first intermediate layer
54 second intermediate layer

### DESCRIPTION OF EMBODIMENTS

Hereinafter, embodiments of the present invention are explained in detail referring to Figures. To facilitate understanding, the scale size of respective members illustrated in Figures may be different from an actual size. In addition, the present invention is not limited to the description below and may be arranged appropriately within the purpose of the present invention. Although an organic photovoltaic cell has a member such as an electrode lead wire, descriptions of such members that are not directly needed to explain the present invention, are omitted. For convenience to explain a layer structure and the like, in the examples illustrated below, explanations are given referring to Figures in which a substrate is arranged in the bottom. However, in an organic photovoltaic cell and a device provided with the organic photovoltaic cell of the present invention, it is not necessary to be arranged in the same manner with this direction corresponding to top, bottom, left and right for manufacturing or using, and an appropriate adjustment may be allowed.

1. Organic Photovoltaic Cell and Device of the present invention

The organic photovoltaic cell of the present invention comprises a pair of electrodes of a first electrode and a second electrode and between the electrodes an active layer comprising an organic compound, and the active layer comprises a metallic oxide nano-particle wearing a carbon material on its surface. In the present description, “a metallic oxide nano-particle wearing a carbon material on its surface” is also referred to as “a carbon wearing) metallic oxide nano particle.”

<Active Layer>

An active layer of the photovoltaic cell is a layer having a function of being activated by light-reception and generating electrical energy. In the organic photovoltaic cell of the present invention, an organic compound, and a carbon wearing metallic oxide nano-particle wherein a carbon material is put on the surface of metallic oxide nano-particle, both coexist in the active layer. As a preferable form of the active layer, a carbon wearing metallic oxide nano-particle may be used as an n-type semiconductor material. By using a carbon wearing metallic oxide nano-particle as an n-type semiconductor material, a cell excellent in light-electricity conversion efficiency can be obtained when adopting various organic semiconductor materials which are used for a p-type semiconductor material.

The carbon wearing metallic oxide nano-particles can be produced less expensively. Also, because the carbon material neutralizes the surface charge of the metallic oxide, the carbon wearing metallic oxide nano-particles are less likely to cohere each other, having excellent dispersibility, and are handled easily during the manufacturing process and the like.

The active layer may be a single layer or a layered body in which multiple layers are stacked. As a formation of the active layer, it may be, for example, a pn heterojunction active layer that is made by stacking a layer formed with a p-type semiconductor material (electron-donor layer) and a layer formed with an n-type semiconductor material (electron-acceptor layer), or a bulk heterojunction active layer that is forming a bulk hetero-junction structure obtained by mixing of a p-type semiconductor material and an n-type semiconductor material.

In the case of forming a pn heterojunction active layer by using carbon wearing metallic oxide nano-particles as one of the semiconductor materials, affinity in the interface between a layer formed with a p-type semiconductor material and a layer formed with an n-type semiconductor material is good, and improvement of a light-electricity conversion rate can be expected.

A preferable form for an active layer includes a form of a bulk heterojunction active layer in which a carbon wearing metallic oxide nano-particle is used as an n-type semiconductor material. When adopting a bulk heterojunction active layer, metallic oxide nano-particles tend to have low compatibility with respective various types of organic semiconductor materials for a p-type semiconductor as a combination. As compared to this, in the present invention, because the surface charge of metallic oxide nano-particles is neutralized by using the carbon wearing metallic oxide nano-particle, the particle has excellent dispersibility, and further various combinations showing good compatibility with a p-type organic semiconductor material can be selected easily. Therefore, an active layer having good bulk hetero-junction structure can be formed, and a high light-electricity conversion efficiency is expected as compared with the case of using the metallic oxide nano-particle of which surface is not modified.

In addition, because a metallic oxide of which surface is not modified does not have adequate electrical conductivity unless the interface between particles strongly adhering to each other, sintering process at a high temperature is needed. For example, in a non patent literature (Journal of Photochemistry and Photobiology A: Chemistry 2004, Volume 164, pp.137-144), a heat treatment is performed at 450° C. to obtain adhesion between particles that are titanium oxide nano-particles of which particle size are 20 nm to 40 nm. However, because in the bulk heterojunction, heat resistance of p-type organic semiconductor mixed therein causes deterioration of properties during the heat treatment at substantially 200° C. or more, a heat treatment at a high temperature can not be performed for obtaining adequate adhesion between metallic oxide nano-particles, and resistance on the interface between particles is high. As compared to this, in the present invention, because the carbon wearing metallic oxide nano-particle is used so that a carbon material having high electrical conductivity exists between metallic oxide nano-particles included in the active layer, a network of metallic oxide nano-particles excellent in the electrical conductivity can be obtained without performing a heat treatment at a high temperature.

In addition, because of having a carbon material on the surface, a function as a current collecting body within the active layer can be expected. Especially, in a case of a bulk heterojunction active layer, because carbon wearing metallic oxide nano-particles have a higher specific gravity and are bulkier than a p-type organic semiconductor material in the active layer, when forming the active layer by applying, the particles can precipitate and form easily a continuous layer. Because the surface of metallic oxide nano-particles are modified with a carbon material, a continuous layer of the carbon material can be formed and an electro-conductive path having a high electro collecting effect can be formed easily in the active layer.

Examples of the carbon material may include a graphite, a fullerene, and a carbon nanotube. As the carbon material, one of these materials may be used alone, or two or more types of these materials may be used in combination. Especially, among these carbon materials, a graphite may be preferably used in view of cost reduction.

As a metallic oxide composing the metallic oxide nano-particles, a material that may become an n-type semiconductor material is favorable. Examples of the metallic oxide that can be an n-type semiconductor material may include oxides of Ti, Nb, Zn or Sn. As the metallic oxide nano-particles, one of these metallic oxides may be used alone, or two or more types of those may be used in combination. As the metallic oxides, TiO₂ is favorable for an n-type semiconductor material.

The carbon material may be put on to the extent that the carbon material neutralizes the surface charge of metallic oxide nano-particles. Within this extent, there is no specific limitation on a proportion of wearing area and a form of wearing state. The carbon material may cover the entire surface of the metallic oxide nano-particles or may be put on a surface of the particles partially. In the case of wearing partially, wearing dispersedly to the whole surface is more preferable than wearing locally.

The active layer provided in the photovoltaic cell comprises an electron-donor compound and an electron-acceptor compound. Being an electron-donor compound or an electron-acceptor compound are relatively determined according to the energy level of an energy level of these compounds.

As the electron-acceptor compound (n-type semiconductor material), the above mentioned carbon wearing metallic oxide nano-particles may be used. As an electron-acceptor compound forming the active layer, other than the carbon wearing metallic oxide nano-particles, an other electron-acceptor compound may be used in combination in addition to the carbon wearing metallic oxide nano-particles. When comprising the other electron-acceptor compound, the weight of the other electron-acceptor compound is preferably 30 wt % or less and is more preferably 10 wt % or less to the total weight of all electron-acceptor compounds. When two or more types of components are used in combination, they may be mixed up and made into one layer, or solo layers made of each component may be stacked each other.

Examples of the other electron-acceptor compounds include: an oxadiazole derivative, anthraquinodimethane and a derivative thereof, benzoquinone and a derivative thereof, naphthoquinone and a derivative thereof, anthraquinone and a derivative thereof, tetracyanoanthraquinodimethane and a derivative thereof, a fluorenone derivative, diphenyldicyanoethylene and a derivative thereof, a diphenoquinone derivative, a metal complexe of 8-hydroxyquinoline and a derivative thereof, polyquinoline and a derivative thereof, polyquinoxaline and a derivative thereof, polyfluorene and a derivative thereof, a fullerene such as C₆₀ fullerene and a derivative thereof, a phenanthrene derivative such as bathocuproine, a metallic oxide such as titanium oxide, and a carbon nanotube. When two or more types of compounds are used in combination, a layer made of each material may be provided, or two or more types of materials may be mixed up and made into one layer.

Examples of a fullerene and a derivative thereof include C₆₀ fullerene, C₇₀ fullerene, C₇₆ fullerene, C₇₈ fullerene, C₈₄ fullerene, and respective derivatives thereof. As a specific structure of the fullerene derivatives, the following are included.

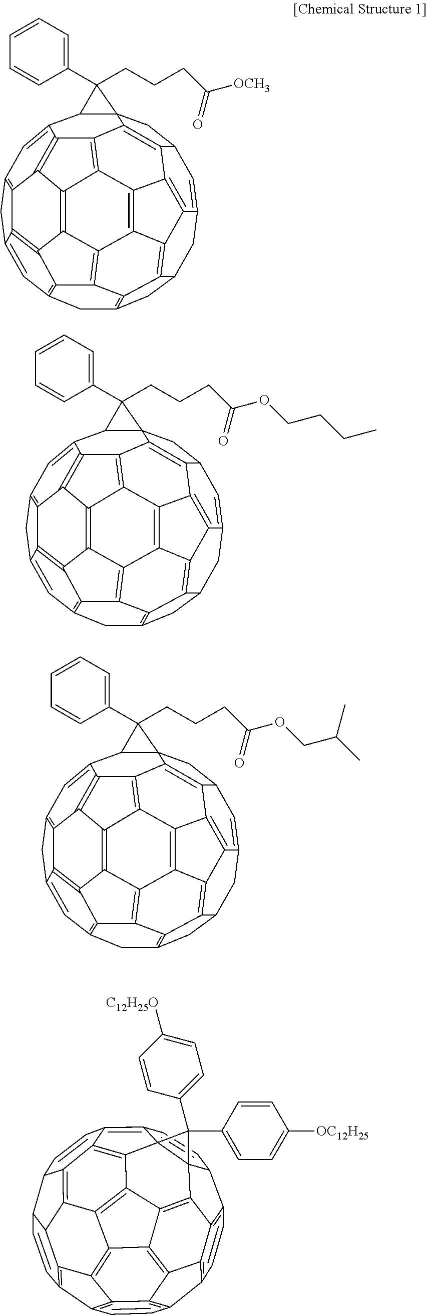

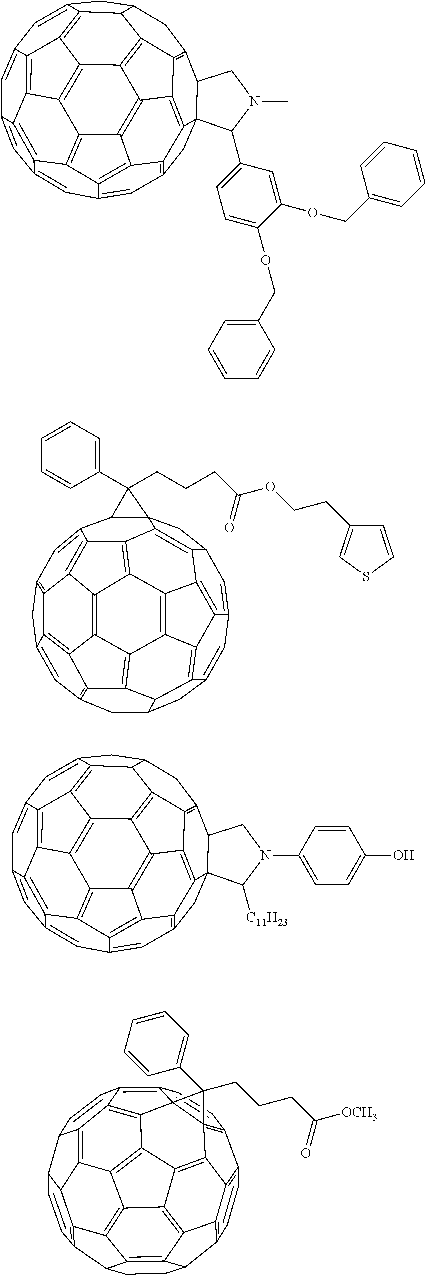

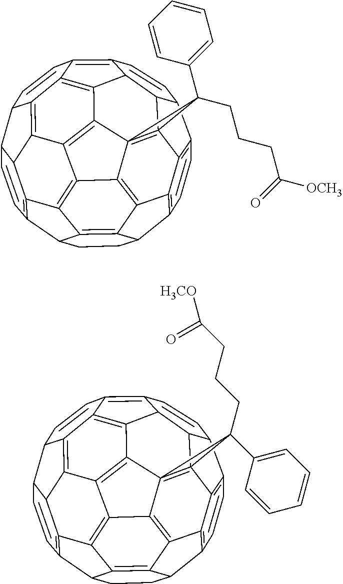

Examples of the fullerene derivative may include PCBM, [6,6]phenyl-C₇₁ butyric acid methyl ester(C₇₀ PCBM; [6,6]-Phenyl C₇₁ butyric acid methyl ester), [6,6]phenyl-C₈₅ butyric acid methyl ester (0₈₄ PCBM; [6,6]-Phenyl C_{H} butyric acid methyl ester), and [6,6]thienyl-C₆₁butyric acid methyl ester([6,6]-Thienyl C₆₁ butyric acid methyl ester).

In the present invention, by using the carbon wearing metallic oxide nano-particles, even when an expensive material such as a fullerene is used, an amount of use of an expensive material such as the fullerene can be reduced to cut the cost of photovoltaic cell.

Examples of the electron-donor compound (p-type semiconductor material) may include a pyrazoline derivative, an arylamine derivative, a stilbene derivative, a triphenyldiamine derivative, an oligothiophene and a derivative thereof, polyvinyl carbazole and a derivative thereof, polysilane and a derivative thereof, a polysiloxane derivative having an aromatic amine in the side chain or main chain, polyaniline and a derivative thereof, polythiophene and a derivative thereof, polypyrrole and a derivative thereof, polyphenylene vinylene and a derivative thereof, and polythienylene vinylene and a derivative thereof.

Usually, a thickness of the active layer is preferably 1 nm to 100 μm and more preferably 2 nm to 1000 nm, further preferably 5 nm to 500 nm, still further preferably 20 nm to 200 nm.

A ratio of electron-acceptor compound in a bulk hetero type of an active layer comprising an electron-acceptor compound and an electron-donor compound is preferably 10 parts by weight to 1000 parts by weight relative to 100 parts by weight of the electron-donor compound, and more preferably 50 parts by weight to 500 parts by weight relative to 100 parts by weight of the electron-donor compound.

<Photovoltaic Cell>

The organic photovoltaic cell is provided with an active layer comprising an organic compound between a pair of electrodes, at least either one of which is transparent or translucent. The outline of an operating mechanism of the photovoltaic cell is explained as the following. A light energy entered from a transparent or translucent electrode is absorbed by an electron-acceptor compound (n-type semiconductor material) and/or an electron-donor compound (p-type semiconductor material) such as a conjugated macromolecular compound, which generates an exciton in which an electron and a hole are bound. When the generated exciton moves and reaches a heterojunction interface at which the electron-acceptor compound and the electron-donor compound are adjacent, the electron and the hole are separated according to the differences in a HOMO energy and a LUMO energy of respective compounds at the interface, and electrical charges (electron and hole) that can move independently are generated. The generated electrical charges move toward respective electrodes and can be extracted to the outside as an electric energy (an electric current).

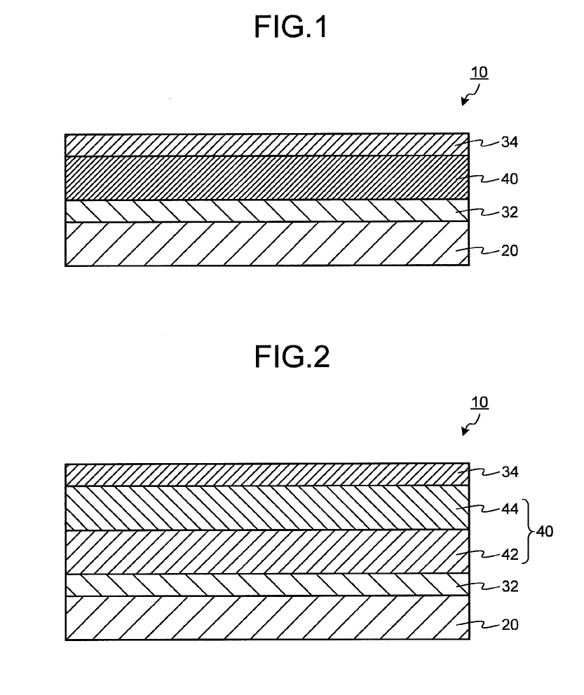

An embodiment of the layered structure of an organic photovoltaic cell is explained referring to FIGS. 1 to 3.

FIG. 1 illustrates a first embodiment of the layered structure. In the first embodiment, an organic photovoltaic cell 10 comprises, a layered body in which an active layer 40 is sandwiched between a pair of electrodes 32 and 34, which is provided on a substrate 20.

In the organic photovoltaic cell, the substrate 20 is an optional component and usually provided for manufacturing reasons and the like. When light is entered from the side of the substrate 20, the substrate 20 is transparent or translucent.

The pair of electrodes 32 and 34 comprises a first electrode 32 provided on the side closer to the substrate and a second electrode 34 opposing to the first electrode. One of the electrodes is an anode and the other is a cathode. There is no specific limitation on whether either the first electrode 32 or the second electrode 34 is an anode or a cathode, and the design may be appropriately changed. At least one of the first electrode 32 and the second electrode 34 is transparent or translucent. When light is entered from the side of the substrate 20, the first electrode 32 is transparent or translucent.

For example, when aluminum (Al) is adopted as a material for a cathode, an evaporation method may be used for film formation. In this case, as a manufacturing process, aluminum evaporation may be preferably a later step depending on an evaporation condition. Therefore, assuming that a manufacturing process includes staking layers in series from a side of the substrate 20, preferably, an embodiment may be adopted, that is the first electrode 32 is an anode and the second electrode 34 is a cathode. Also, because in some cases it may be difficult to make an aluminum electrode transparent or translucent depending on a predetermined thickness, an embodiment may be adopted in such the case, that is, light is entered from the side of the substrate 20. When light is entered from the side of the substrate 20, the substrate 20 and the first electrode 32 are formed to be transparent or translucent.

In the first embodiment, one active layer 40 is provided. In a cell of the first embodiment, the active layer 40 is a bulk heterojunction active layer, in which a p-type semiconductor material and an n-type semiconductor material have a bulk hetero-junction structure.

FIG. 2 illustrates a second embodiment of the layered structure. The same components with those in the first embodiment are indicated with the same letters or numerals and descriptions of them are omitted. In the second embodiment, the active layer 40 is a pn heterojunction active layer comprising two layers of a first active layer 42 and a second active layer 44. One of these layers is an electron-acceptor layer that is formed with an n-type semiconductor material. The other layer is an electron-donor layer that is formed with a p-type semiconductor material. There is no specific limitation on whether either the first active layer 42 or the second active layer 44 is an electron-acceptor layer or an electron-donor layer, and the design may be appropriately changed.

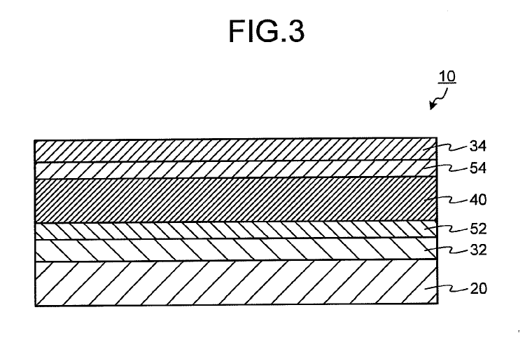

FIG. 3 illustrates a third embodiment of the layered structure. The same components with those in the first embodiment are indicated with the same letters or numerals and descriptions of them are omitted. In the third embodiment, a first intermediate layer 52 is provided between the active layer 40 and the first electrode 32, and a second intermediate layer 54 is provided between the active layer 40 and the second electrode 34. In FIG. 3, although two intermediate layers are provided, one layer either of two may be provided. In addition, although in FIG. 3 each intermediate layer is indicated as a single layer, every intermediate layer may comprise a multiple layered structure.

Intermediate layers may have a wide variety of functions. In a case that the first electrode 32 is an anode, the first intermediate layer 52 may be, for example, a hole transport layer, an electron block layer, and a layer with another function. In this case, the second electrode 34 is a cathode, and the second intermediate layer 54 may be, for example, a hole transport layer, an electron block layer, and a layer with another function. In another case that, by replacing the electrodes with each other, the first electrode 32 is a cathode and the second electrode 34 is an anode, positions of the intermediate layers are accordingly exchanged each other.

As a preferable embodiment for an organic photovoltaic cell of the present invention, a following embodiment is included: an intermediate layer is provided between at least one either of electrodes and the active layer, and carbon wearing metallic oxide nano-particles are comprised in the intermediate layer wherein the above carbon material is put on the surface of the metallic oxide nano-particles.

As a material used for the intermediate layer, for example, alkali metals such as lithium fluoride, halides of alkaline earth metals, and oxides may be used. In addition, fine particles of an inorganic semiconductor such as titanium oxide, and PEDOT (poly-3,4-ethylenedioxythiophene) are included.

An organic photovoltaic cell, generally, is formed on a substrate. The substrate may be any substrate that can be provided with an electrode and is not chemically changed during forming a layer of an organic material. A material for the substrate include, for example, a glass, a plastic, a macromolecular film, and silicon. In case of a non-transparent substrate, opposite electrode (that is an electrode farther from the substrate) is preferably transparent or translucent.

As transparent or translucent electrodes, a metallic oxide film having electrical conductivity, and a translucent metallic thin film are included. In particular, a film made from an electrically conductive material of indium oxide, zinc oxide, tin oxide, a complex thereof such as indium-tin-oxide (ITO), indium-zinc-oxide or the like, and a film of NESA and the like, gold, platinum, silver, copper or the like, are used. Preferably, a film made from ITO, indium-zinc-oxide, or tin oxide are used. Production methods of an electrode include vacuum evaporation, sputtering, ion plating, plating and the like. As an electrode, an electrically conducting organic transparent film of polyaniline or a derivative thereof, polythiophene or a derivative thereof, or the like may be used.

When one electrode is transparent or translucent, the other electrode is not necessarily transparent. Depending on a predetermined thickness, as an electrode material for a non-transparent electrode, a metal or an electrically conductive macromolecule may be used. Specific examples of the electrode material may include: a metal such as lithium, sodium, potassium, rubidium, cesium, magnesium, calcium, strontium, barium, aluminum, scandium, vanadium, zinc, yttrium, indium, cerium, samarium, europium, terbium, and ytterbium; an alloy of two or more of these metals; an alloy of one or more type(s) of the above metals and one or more type(s) of metals selected from the group consisting of gold, silver, platinum, copper, manganese, titanium, cobalt, nickel, tungsten, and tin; a graphite; a graphite intercalation compound; polyaniline and a derivative thereof; and polythiophene and a derivative thereof. As an alloy, the following are included: a magnesium-silver alloy, a magnesium-indium alloy, a magnesium-aluminum alloy, an indium-silver alloy, a lithium-aluminum alloy, a lithium-magnesium alloy, a lithium-indium alloy, and a calcium-aluminum alloy.

<Device Provided with an Organic Photovoltaic Cell>

The photovoltaic cell of the present invention generates photovoltaic power between the electrodes by irradiating a side of the transparent or translucent electrode with light such as solar light, and thus can serve as an organic thin film solar cell. Also, it can be used as an organic thin film solar cell module by collecting multiple organic thin film solar cells.

Also, under a condition of applying or not applying a voltage between the electrodes, photocurrent is generated by irradiating a side of the transparent or translucent electrode with light, and thus the cell can work as an organic photosensor. Also, by collecting multiple organic photosensors, it can be used as an organic image sensor device.

<Solar Cell Module>

An organic thin film solar cell may basically have the same module structure as that of a conventional solar cell module. The solar cell module has a structure in which a cell is provided usually on a supporting substrate made from a material such as a metal or a ceramic, the top of which is covered with a filling resin, a protection glass or the like. In the structure, light is entered from the side opposite to the supporting substrate. Or, it may have a structure that, the supporting substrate is made of a transparent material such as a tempered glass on which the cell is provided and light is entered from the side of transparent supporting substrate. For example, well-known structures are included: a module structure called as a superstraight type, a substrate type or a potting type; and a substrate-integrated module structure used for amorphous-silicon solar cell. In the organic thin film solar cell of the present invention, a module structure may be selected appropriately from these module structures depending on a purpose for using, a place of using and an environment.

A representative example of a superstraight type or a substrate type of module has a structure that: cells are provided at a regular interval between supporting substrates one or both of which are transparent and subjected to an antireflection treatment; adjacent cells are connected by a metal lead or a flexible wire; a current-collecting electrode is arranged on the outer edge part; and generated power is extracted to outside. Between a substrate and a cell, for protection of the cell and improving current-collecting efficiency, various types of plastic materials such as ethylene-vinyl acetate (EVA) may be used as a film or a filling resin depending on a purpose. In a case of using for such a location where an impact from an outside is less or it is not necessary for covering a surface with a hard material, a surface protection layer may be provided with a transparent plastic film or the above filling resin may be cured to give a protective function, and therefore one side of supporting substrates may be omitted. A periphery of the supporting substrate is fixed like in a sandwiched state with a metallic frame for sealing an inside and ensuring rigidity of the module, and the inside between the supporting substrate and the frame is completely sealed with a sealing material. When an elastic material is used for the cell itself, a supporting substrate, a filling material and a sealing material, a solar cell may be provided on a curved surface.

In a case of the solar cell using a flexible support such as a polymer film, cells are manufactured in sequence by sending and taking out a roll-shaped support, and after cutting out the cells in a desired size, a peripheral edge is sealed with a flexible and moisture-proof material, thereby manufacturing a cell body. Also, it may become a module structure called as “SCAF” in the description of Solar Energy Materials and Solar Cells, 48, p383-391. In addition, a solar cell using a flexible support may be used by adhering and being fixed to a curved glass or the like.

2. Manufacturing Method of Organic Photovoltaic Cell and Device

The organic photovoltaic cell of the present invention may be manufactured by a method for manufacturing an organic photovoltaic cell comprising a pair of electrodes of a first electrode and a second electrode and an active layer comprising an organic compound between the pair of electrodes, and the manufacturing method comprises a step of forming the active layer comprising a metallic oxide nano-particle wearing a carbon material on its surface.

<Method for Putting a Carbon Material on a Surface of the Metallic Oxide Nano-Particle>

As described above, a carbon material may be put on to the extent that the carbon material neutralizes surface charge of a metallic oxide nano-particle; within this extent, there is no specific limitation on a proportion of adhering area and a form of adhering state. Also, there is no specific limitation on a method for putting a carbon material on the surface of a metallic oxide nano-particle, and a method such as a surface treatment for fine metallic particles may be adopted. As an example of the method for putting a carbon material on the surface of a metallic oxide nano-particle, the following embodiments are included. First, metallic oxide nano-particles are prepared and dispersed in a fluid to prepare slurry. Then a carbon material is added in the slurry and mixed by stirring fully. Solid content is recovered by filtration or the like, and then the obtained solid content is dried. In this way, metallic oxide nano-particles wearing a carbon material (carbon wearing metallic oxide nano-particles) can be obtained.

Further, as examples of the method for preparing carbon wearing metallic oxide nano-particles (method for preparing particles), the following embodiments (1) to (3) are also included.

(1) Mixing Metallic Oxide raw material and Carbon Material

The carbon material is added in a solution comprising a metallic oxide raw material (e.g. a metalloorganic salt, a carbonate, a hydrochloride, a sulfate, and a hydroxide) and stirred. A water heat treatment is performed, and the obtained solution in which a crystallized metallic oxide and the carbon material are mixed, is subjected to solid-liquid separation, and then a drying treatment is performed, thereby obtaining carbon wearing metallic oxide nano-particles.

(2) Mixing Metallic Oxide Nano-Particles and Carbon Material Raw Material

To a slurry in which a metallic oxide is dispersed, a raw material of carbon material is added, and then the obtained is stirred and mixed adequately. Then, a solid substance is recovered by solid-liquid separation, and a carbon reduction treatment is performed under an inert atmosphere (N₂), thereby obtaining carbon wearing metallic oxide nano-particles.

(3) Water Heat Treatment of Metallic Oxide Nano-Particle Raw Material and Raw Material of Carbon Material

An aqueous solution comprising a raw material of metallic oxide nano-particles and a raw material of a carbon material (water soluble polymers such as saccharide and polyethylene glycol) is subjected to a water heat treatment, crystallizing simultaneously the oxide nano-particles and the carbon material, and carbon adhering oxide nano-particles are obtained. Alternatively, instead of the water heat treatment, a precipitate deposited from the aqueous solution by a method such as coprecipitation is heat-treated under an inert atmosphere, and then carbon wearing metallic oxide nano-particles are obtained.

<Method for Forming Active Layer>

A method for forming an active layer is not limited specifically except that carbon wearing metallic oxide nano-particles are included in the active layer. As a method for forming an active layer, a wide variety of thin film formation methods may be adopted according to a material of the active layer. A method for forming an active layer includes, for example, film formation from a solution or a dispersion comprising components such as a macromolecular compound, and film formation by vacuum evaporation.

An active layer in the organic photovoltaic cell of the present invention comprises an organic compound in the active layer regardless of types of an active layer such as pn heterojunction or bulk heterojunction. Therefore, for forming an active layer, a wide variety of film formation methods for a layer made of organic compounds may be adopted.

When forming a layer comprising an organic compound, for example, a solution in which the organic compound is dissolved in a solvent is prepared, and film formation may be performed by adopting a method in which a film is formed by using a liquid. A solvent used for the film formation from a solution is appropriately selected depending on types of a material comprised in the active layer. Solvents such as water or an organic solvent may be used. Examples of the organic solvents may include: unsaturated hydrocarbon solvents such as toluene, xylene, mesitylene, tetralin, decalin, bicyclohexyl, butylbenzene, sec-butylbenzene, and tert-butylbenzene; halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, and bromocyclohexane; halogenated unsaturated hydrocarbon solvents such as chlorobenzene, dichlorobenzene, and trichlorobenzene; and ether solvents such as tetrahydrofuran and tetrahydropyran.

Examples of a film formation method in which liquid is used as a material for forming a layer (including a liquid substance such as an ink) may include: coating methods such as a spin coating method, a casting method, a micro gravure coating method, a gravure coating method, a bar coating method, a roll coating method, a wire bar coating method, a dip coating method, a spray coating method, a screen printing method, a gravure printing method, a flexo printing method, an offset printing method, an inkjet printing method, a dispenser printing method, a nozzle coating method, and a capillary coating method. Preferably, the spin coating method, the flexo printing method, the gravure printing method, the inkjet printing method, and the dispenser printing method are included.

When forming a bulk heterojunction active layer as an active layer, as mentioned in the above, a film formation method using a liquid may be adopted. As one embodiment for providing a bulk heterojunction active layer, for example, a mixed liquid comprising two types components is prepared as a coating liquid, in which one of the two components is a p-type organic semiconductor material and the other is a n-type semiconductor material of metallic oxide nano-particles wearing a carbon material on their surfaces, and using the prepared mixed liquid(as a coating liquid), the active layer may be formed by a film formation method such as a coating method in the same manner as described above.

When forming a pn heterojunction active layer comprising a multiple layered structure as an active layer, film formation of an electron-acceptor layer and an electron-donor layer may be separately performed in order. A film formation method may be appropriately selected depending on a material for respective layers. For example, a coating liquid in which a p-type organic semiconductor material is dissolved is initially prepared, and then this is applied on an electrode or an intermediate layer, followed by volatilizing a solvent, thereby forming an electron-donor layer. Next, a dispersion liquid is prepared, in which metallic oxide nano-particles of which surfaces a carbon material adhering to are dispersed in a dispersion medium, and then this is applied on the electron-donor layer, followed by volatilizing the dispersion medium, thereby forming an electron-acceptor layer. In this way, an active layer having a structure composed of two layers may be formed. The order of forming the electron-donor layer and the electron-acceptor layer may be a reversed, contrary to the order described in the above. Examples of the dispersion medium may include: an alcohol such as methanol, ethanol, isopropyl alcohol, and tert-butyl alcohol; and a saturated hydrocarbon such as hexane, heptane, octane, and decane.

<Method for Forming Other Layers>

A method for forming other layers other than the active layer (electrode, intermediate layer and the like) is not limited specifically, and a method may be appropriately selected from various thin film formation methods, considering conditions such as a type of materials and a thickness of designed layers. When using a solution as a raw material for film formation, the film formation methods such as a coating method as described above are included. In addition, vacuum evaporation, sputtering, and chemical vapor deposition (CVD), or the like, may be adopted.

<Manufacturing Device>

The organic photovoltaic cell of the present invention may be made into a device such as a solar cell module and an organic image sensor by providing an electrical wiring, other electrical parts and the like according to a usual method for manufacturing an electrical machinery.

### EXAMPLES

<Synthesis of Carbon Adhering Titanium Oxide Nano-Particles>

[Preparation of Slurry of Ti-comprising Compound]

Using a titanium sulfate (IV) solution (produced by KANTO CHEMICAL Co., Ltd.; diluted into 12 mass % titanium sulfate) and NH₃ water (produced by KANTO CHEMICAL Co., Ltd.; diluted into 4 mass %), neutralization was performed, and the obtained precipitate was filtered and washed. Thus, a Ti-comprising compound was obtained. This Ti-comprising compound was dispersed in NH₃ water having an adjusted pH of 10.5 at a concentration of 1 mass %, and thereby a Ti-comprising compound slurry was obtained.

[Preparation of Carbon Adhering Titanium Oxide Nano-Particles]

The Ti-comprising compound slurry was used as a raw material of metallic oxide. Glucose (produced by Wako Pure Chemical Industries, Ltd.) was used as a raw material of carbon material. After 12 g of glucose was added to 1200 mL of the Ti-comprising compound slurry, the mixture was charged into a Hastelloy pressure reactor and treated under a supercritical state of 380° C. Then, the recovered product of slurry was subjected to a solid-liquid separation by filtration, and was dried under the conditions of a temperature of 60° C. and a duration of 3 hours. Thus, a mixed precursor was obtained. The mixed precursor was put into an alumina boat, and this was heated in a tube shaped electric furnace having an inner volume of 13.4 L, with a circulating nitrogen gas at a rate of 1.5 L/min from a room temperature (about 25° C.) to 800° C. at a temperature elevation rate of 300° C/hour. The baking was performed by keeping at 800° C. for 1 hour, and thus the resultant was obtained as a product 1. The obtained product 1 was carbon adhering titanium oxide nano-particles wherein carbon was put on the surfaces of titanium oxide nano-particles.

<Manufacturing Method of an Organic Thin Film Photovoltaic Cell>

After a glass substrate (substrate) coated with an ITO film having a thickness of 150 nm by sputtering was washed using acetone, by an ultraviolet ozone irradiator (produced by Technovision, Inc.; Type: UV-312) equipped with a low pressure mercury vapor lamp, a UV-ozone cleaning treatment was performed for 15 minutes, and thereby an ITO electrode (first electrode, anode) having a cleaned surface was obtained.

Next, PEDOT (produced by Starck GmbH; product name: Baytron P AI4083; lot.HCD07O109) was applied to the surface of the ITO electrode by spin coating. Then, the obtained coated ITO electrode was dried at 150° C. for 30 minutes in the atmosphere, and thereby a PEDOT layer (first intermediate layer) was obtained.

Poly(3-hexylthiophene)(P3HT; produced by Merck & Co., Inc.; product name: lisicon SP001; lot.EF431002) as a conjugated macromolecular compound, and the carbon wearing titanium oxide nano-particles (product 1) that were TiO₂ nano-particles of which surfaces a carbon material is put on, were added together in an o-dichlorobenzene solvent so that P3HT was made to be 1.5 wt % and the carbon adhering titanium oxide nano-particles were made to be 1.2 wt %. After the addition, stirring was performed at 70° C. for 2 hours followed by filtration with a filter having a pore size of 0.2 μm, and thereby a solution as a coating liquid 1 was obtained. On the PEDOT layer (first intermediate layer), the coating liquid 1 was applied by a spin coating method to form an active layer. Then, a heat treatment was performed at 150° C. for 3 minutes in the atmosphere of nitrogen gas. After the heat treatment, the film thickness of the active layer was about 100 nm. Then, Al was evaporated to a thickness of 70 nm in a vacuum evaporation apparatus. All degrees of vacuum during evaporation were 1×10⁻⁴ Pa to 9×10⁻⁴ Pa. Thus, an Al layer (second electrode, cathode) was provided.

The shape of the organic thin film photovoltaic cell was made to be a 2 mm×2 mm regular tetragon. The power generation property of the obtained organic thin film photovoltaic cell was measured by using a solar simulator (produced by Yamashita Denso; product name: YSS-80) and irradiating with light through an AM1.5G filter by a irradiance of 100 mW/cm², and then the power generation was confirmed by measuring the generated current and voltage.

### INDUSTRIAL APPLICABILITY

The present invention is useful for providing an organic photovoltaic cell.

1. An organic photovoltaic cell comprising:
a pair of electrodes of a first electrode and a second electrode; and
an active layer comprising an organic compound, provided between the pair of electrodes, wherein the active layer comprises a metallic oxide nano-particle wearing a carbon material on its surface.

2. The organic photovoltaic cell according to claim 1, wherein the carbon material is selected from the group consisting of a graphite, a fullerene, a fullerene derivative and a carbon nanotube.

3. The organic photovoltaic cell according to claim 1, wherein the metallic oxide constituting the metallic oxide nano-particle is an n-type semiconductor material.

4. The organic photovoltaic cell according to claim 1, wherein the metallic oxide constituting the metallic oxide nano-particle is a metallic oxide made from a metal selected from the group consisting of Ti, Nb, Zn, and Sn.

5. A method for manufacturing an organic photovoltaic cell comprising a pair of electrodes of a first electrode and a second electrode, and an active layer comprising an organic compound and being provided between the pair of electrodes, the manufacturing method comprising the step of:
forming the active layer comprising a metallic oxide nano-particle wearing a carbon material on its surface.

6. The method for manufacturing an organic photovoltaic cell according to claim 5, wherein the metallic oxide nano-particle wearing a carbon material on its surface is produced by a particle-preparation method including the steps (A) and (B):
(A) preparing a mixed solution of a slurry comprising a raw material of the metallic oxide and a raw material of the carbon material; and
(B) performing a supercritical water heat treatment to the mixed solution.

7. An organic photovoltaic cell manufactured by the method according to claim 6, wherein the raw material of the carbon material is a saccharide.

8. A solar cell module comprising the organic photovoltaic cell according to claim 1.

9. An image sensor device comprising the organic photovoltaic cell according to claim 1.
